(19) United States
(12) Patent Application Publication
(10) Pub. No.: US 2006/0044055 A1
(43) Pub. Date: Mar. 2, 2006

(54) Negative-resistance circuit and active filter

(76) Inventors: Masaharu Ito, Tokyo (JP); Kenichi Maruhashi, Tokyo (JP); Shuya Kishimoto, Tokyo (JP); Keiichi Ohata, Tokyo (JP)

Correspondence Address: YOUNG & THOMPSON, 745 SOUTH 23RD STREET, 2ND FLOOR, ARLINGTON, VA, 22202, US

(21) Appl. No.: 10/537,661

(22) PCT Filed: Dec. 4, 2003
(86) PCT No.: PCT/JP03/15523

§ 371 Date: Jun. 6, 2005

(30) Foreign Application Priority Data
Dec. 6, 2002 (JP) 2002-355307

(51) Int. Cl. H03K 5/00

(52) U.S. Cl. 327/552

(57) ABSTRACT

A negative resistance circuit having a transistor and a plurality of distributed constant lines respectively connected to the three terminals of the transistor further comprises an inductive element or a capacitive element connected between the output terminal of the negative resistance circuit and the ground potential. The negative resistance is adjusted through the inductance of the inductive element or the capacitance of the capacitive element.

### TECHNICAL FIELD

The present invention relates to a negative-resistance circuit which employs a transistor and a distributed constant line, and an active filter which employs the negative-resistance circuit.

### BACKGROUND ART

Negative-resistance circuits are used in oscillator circuits, active filters and the like for use in high frequency bands such as microwaves, millimeter-waves and the like. A configuration illustrated in FIG. 1 has been conventionally known as a negative-resistance circuit.

FIG. 1 is a configuration similar to a voltage controlled oscillator circuit described, for example, in FIG. 1 of Patent Document 1 (JP-10-93348-A). In Patent Document 1, constants are set for respective elements which make up an oscillator and a negative-resistance circuit in order to implement a circuit which oscillates in a desired frequency range. However, even in the configuration described in Patent Document 1, if constants are appropriately selected for the respective elements, the resulting circuit will not oscillate. Further, an active filter can also be made by using the circuit illustrated in FIG. 1 in combination with a plurality of capacitance elements and inductance elements. The following description will be made on the assumption that the circuit illustrated in FIG. 1 is utilized as an active filter.

As illustrated in FIG. 1, the conventional negative-resistance circuit comprises field effect transistor (FET) 101, and is configured to have negative resistance R_{N} by positively feeding back from drain (D) to gate (G) of FET 101. Connected to the source of FET 101 is first distributed constant line (the length of which is ls) 102d which is capacitive in a desired frequency range, grounds source (S) in a direct current manner, and has a length set in λ/4<ls<λ/2 (λ is one wavelength at a desired frequency).

Capacitance element 107a is connected to gate (G) of FET 101 for short-circuiting to a ground potential through second distributed constant line (the length of which is lg) 103 in a high frequency manner. Also, the gate of FET 101 is applied with predetermined bias voltage Vg by bias power source 106 through second distributed constant line 103.

Third distributed constant line (the length of which is ld) 104 is connected to the drain of FET 101, and fourth distributed constant line 117 is connected to third distributed constant line 104 for short-circuiting the drain to the ground potential by capacitance element 107b in a high frequency manner. Also, the drain of FET 101 is applied with bias voltage Vd by bias power source 105, which is connected in parallel with capacitance element 107b, through third and fourth distributed constant lines 104, 117. The length of fourth distributed constant line 117 is set to one-quarter wavelength at the desired frequency. By setting fourth distributed constant line 117 to such a length, fourth distributed constant line 117 has an infinite impedance at the desired frequency, as viewed from a connection of third distributed constant line 104 with fourth distributed constant line 117. In this way, the influence of fourth distributed constant line 117 can be ignored at the desired frequency.

Capacitance element 108, which presents low reactance at high frequencies, is inserted between third distributed constant line 104 and an output terminal in order to prevent bias voltage Vd applied to the drain of FET 101 from leaking from the output terminal.

A negative resistance value of the negative-resistance circuit illustrated in FIG. 1 is adjusted by length ls of first distributed constant line 102d, length lg of second distributed constant line 103, and length ld of third distributed constant line 104 connected to the three terminals (S, G, D) of FET 101.

For configuring a wide-band active filter using the negative-resistance circuit illustrated in FIG. 1, a negative-resistance circuit is required to have a constant negative resistance value over a wide band in order to implement a circuit which stably operates without oscillating.

When an active filter is composed, for example, of resonator 119 including a distributed constant line having a length equal to n/4 (n is a positive integer) wavelengths at a desired frequency, and negative-resistance circuit 118 for terminating resonator 119, resistance value RN of negative-resistance circuit 118 must be set as described below in order to ensure that resonator 119 is lossless. A terminal of resonator 119 which is not connected to negative-resistance circuit 118 is opened when n is an odd number and is short-circuited to the ground potential when n is an even number.

First, the loss L connected with the electromagnetic waves that travel from negative-resistance circuit 118 that are reflected by the other end of resonator 119, and return to negative-resistance circuit 118 is represented by the below Equation (1).

Reflection gain Γ of negative-resistance circuit 118 is represented by the below Equation (2).

Therefore, entire resonator 119 can be regarded as lossless when the condition of below Equation (3) is satisfied. Solving Equation (3) for negative resistance value R_{N} results in Conditional Equation (4) which should be satisfied by negative resistance value R_{N}.

$$\begin{matrix}[ Equation 1 ] & \\ L = {ⅇ}^{- n λα / 2} & ( 1 ) \\ Γ = \vert \frac{{R}_{N} - {Z}_{0}}{{R}_{N} + {Z}_{0}} \vert & ( 2 ) \\ L \times Γ = 1 & ( 3 ) \\ {R}_{N} = \frac{- {Z}_{0} ( {ⅇ}^{n λα / 2} - 1 )}{{ⅇ}^{n λα / 2} + 1} & ( 4 )\end{matrix}$$

where Z₀ is the characteristic impedance of the distributed constant line, λ is the wavelength at the desired frequency, and α is an attenuation constant.

The absolute value of the negative resistance expressed by this Equation (4) is on the order of several Ω (for example, for a one-quarter wavelength coplanar line type resonator formed on GaAs and having a distance of 70 μm to the ground, the result of a calculation made by an electromagnetic field simulator indicated approximately 1 Ω).

In an actual circuit, the negative resistance value is larger than the foregoing Equation (4) due to losses caused by radiation at the connection of resonator 119 with negative-resistance circuit 118 and at the open end (or short-circuited end), but a resistance value required when used as an active filter is generally 10 Ω or less.

The frequency characteristic of the negative resistance value of the conventional negative-resistance circuit illustrated in FIG. 1 is shown by a graph in FIG. 3. FIG. 3 shows the result of a simulation.

As shown in FIG. 3, the negative-resistance circuit illustrated in FIG. 1 achieves a constant and relatively small negative resistance value from 35 GHz to 60 GHz, but the negative resistance value suddenly increases beyond 60 GHz, and thereafter suddenly decreases. In other words, the negative-resistance circuit illustrated in FIG. 1 experiences difficulties in achieving a constant negative resistance value over a wide band, particularly, a small negative resistance value on the order of several Ω.

Also, the conventional active filter using a negative-resistance circuit has a problem that variations in characteristics of the FET cause large fluctuations in the filter characteristics because negative-resistance circuit 118 is directly connected to resonator 119. Thus, the lengths of the distributed constant lines connected to the respective terminals of the FET must be adjusted separately in order to achieve desired filter characteristics, causing a problem that the adjustment is difficult.

It is an object of the present invention to provide a negative-resistance circuit having distributed constant lines, which achieves a constant negative resistance value over a wide band in a structure which facilitates adjustments.

### DISCLOSURE OF THE INVENTION

To achieve the above object, a negative-resistance circuit of the present invention comprises an inductance element or a capacitance element connected between an output terminal of the negative-resistance circuit and a ground potential. Also, a plurality of distributed constant lines are connected in parallel to at least one of three terminals of the transistor (particularly, a source when the transistor is a field effect transistor). The negative-resistance circuit in such a configuration can be readily adjusted to achieve a constant negative resistance value over a wide frequency range.

Further, the negative-resistance circuit of the present invention is configured to have the output terminal on the gate side of the field effect transistor. Such a configuration eliminates the need for a distributed constant line on the output side, required for a conventional negative-resistance circuit, which presents small impedance to a direct current, and an infinite impedance at a desired frequency. Consequently, the circuit configuration is simplified, as compared with the conventional configuration, making it possible to reduce the size.

An active filter of the present invention, in turn, is assembled using the negative-resistance circuit of the present invention which has a constant negative resistance value over a wide band. In such a configuration, it is possible to achieve a filter circuit which operates stably without oscillating.

### BRIEF EXPLANATION OF THE DRAWINGS

FIG. 1 is a circuit diagram illustrating the configuration of a conventional negative-resistance circuit;

FIG. 2 is a circuit diagram illustrating an exemplary configuration of a resonator which employs the negative-resistance circuit illustrated in FIG. 1;

FIG. 3 is a graph showing the frequency characteristic of the negative resistance value of the negative-resistance circuit illustrated in FIG. 1;

FIG. 4 is a circuit diagram illustrating the configuration of a first embodiment of a negative-resistance circuit according to the present invention;

FIG. 5A is a top plan view illustrating the layout of a symmetric inductance element used in the negative-resistance circuit of FIG. 4;

FIG. 5B is a top plan view illustrating the layout of an asymmetric inductance element used in the negative-resistance circuit of FIG. 4;

FIG. 6 is a graph showing the result of a simulation, representing a change in inductance with respect to the length of a distributed constant line when the inductance element shown in FIG. 4 is made of the distributed constant line;

FIG. 7 is a graph showing how the frequency characteristics of the negative resistance value change depending on the length of a third distributed constant line shown in FIG. 4;

FIG. 8 is a graph showing how the frequency characteristics of the negative resistance value change depending on the length of a second distributed constant line shown in FIG. 4;

FIG. 9 is a graph showing how the frequency characteristics of the negative resistance value change depending on the value of the inductance element shown in FIG. 4;

FIG. 10 is a circuit diagram illustrating an equivalent circuit of the negative-resistance circuit illustrated in FIG. 4;

FIG. 11 is a circuit diagram illustrating the configuration of a second embodiment of the negative-resistance circuit according to the present invention;

FIG. 12 is a graph showing a change in phase of a reflection coefficient with respect to the frequency regarding a first distributed constant line and a fourth distributed constant line, as viewed from a source of an FET shown in FIG. 11;

FIG. 13 is a graph showing how the frequency characteristics of the negative-resistance value of the negative-resistance circuit illustrated in FIG. 11 change depending on the value of an inductance element;

FIG. 14 is a circuit diagram illustrating the configuration of a third embodiment of the negative-resistance circuit according to the present invention;

FIG. 15 is a graph showing a change in phase of a reflection coefficient with respect to the frequency regarding a fifth distributed constant line and a sixth distributed constant line, as viewed from a source of an FET shown in FIG. 14;

FIG. 16 is a circuit diagram illustrating the configuration of a fourth embodiment of the negative-resistance circuit according to the present invention;

FIG. 17 is a top plan view illustrating an exemplary layout of a capacitance element used in the negative-resistance circuit illustrated in FIG. 16;

FIG. 18 is a circuit diagram illustrating an equivalent circuit of the negative-resistance circuit illustrated in FIG. 16;

FIG. 19 is a circuit diagram illustrating the configuration of a fifth embodiment of the negative-resistance circuit according to the present invention;

FIG. 20 is a circuit diagram illustrating an exemplary configuration of an active filter according to the present invention; and

FIG. 21 is a circuit diagram illustrating another exemplary configuration of the active filter according to the present invention.

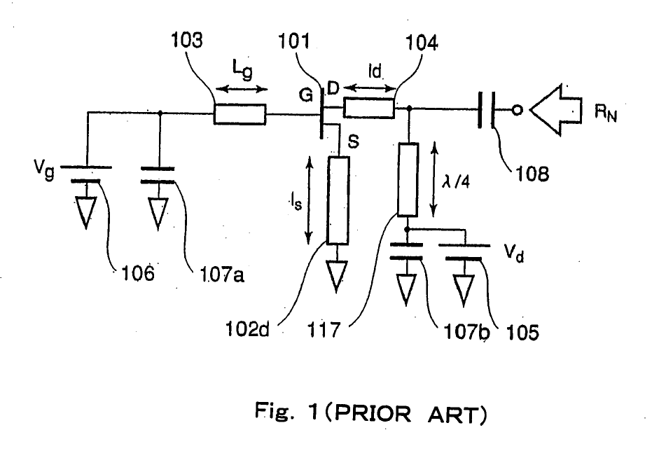

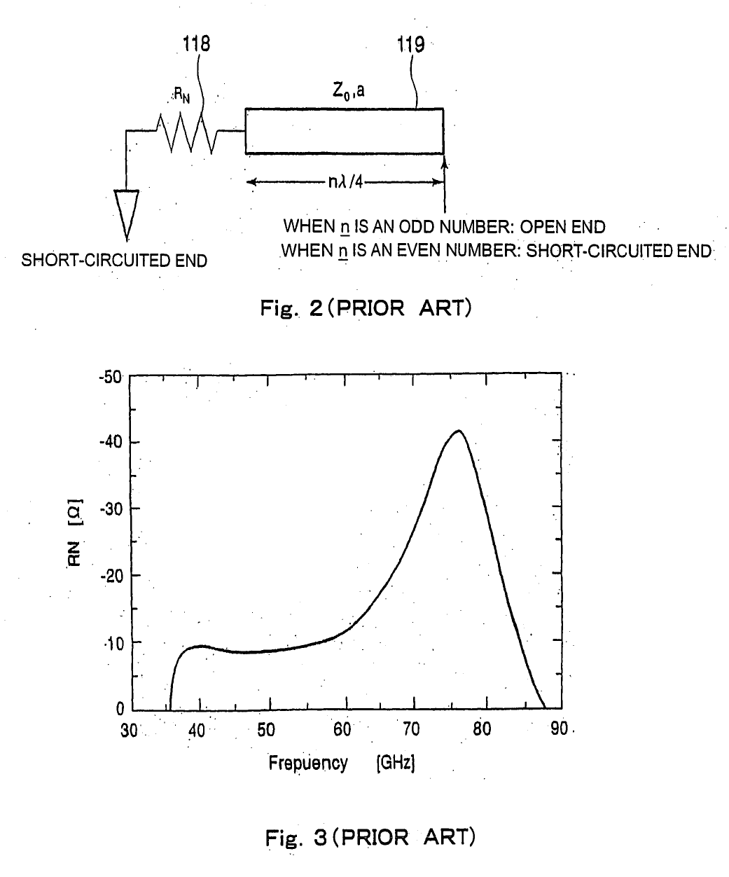

### BEST MODE FOR CARRYING OUT THE INVENTION

### First Embodiment

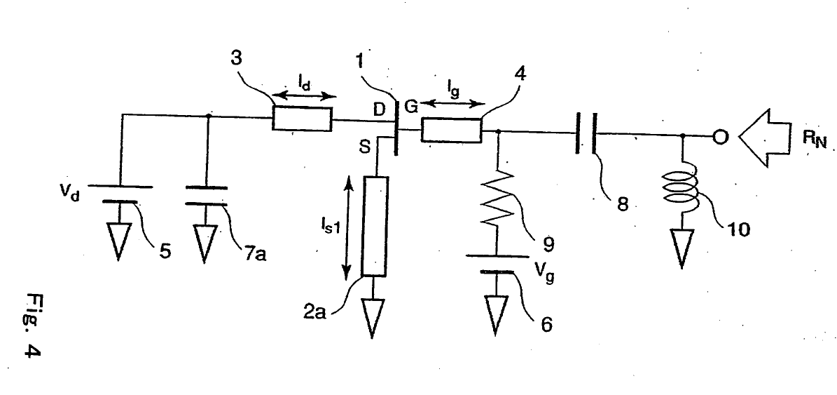

A negative-resistance circuit according to a first embodiment of the present invention comprises field effect transistor (FET) 1, as illustrated in FIG. 4, and is configured to have negative resistance R_{N} by positively feeding back from drain (D) to gate (G) of FET 1. Connected to a source of FET 1 is first distributed constant line (the length of which is ls1) which is capacitive in a desired frequency range, grounds the source in a direct current manner, and has a length set in a range λ/4<ls<λ/2 (λ is one wavelength at a desired frequency).

Capacitance element 7a is connected to drain (D) of FET 1 through second distributed constant line (the length of which is ld) 3 for short-circuiting to a ground potential in a high frequency manner. Also, the drain of FET 1 is applied with predetermined bias voltage Vd by bias power source 5 through second distributed constant line 3.

Third distributed constant line (the length of which is lg) 4 is connected to the gate of FET 1. Also, the gate of FET 1 is applied with predetermined bias voltage Vg by bias power source 6 through resistor 9 having a large resistance value (several KΩ). Capacitance element 8, which presents a low reactance at high frequencies, is inserted between third distributed constant line 5 and an output terminal in order to prevent bias voltage Vg applied to the gate of FET 1 from leaking from the output terminal. Further, inductance element 10 is connected between the output terminal and ground potential for adjusting the negative resistance value.

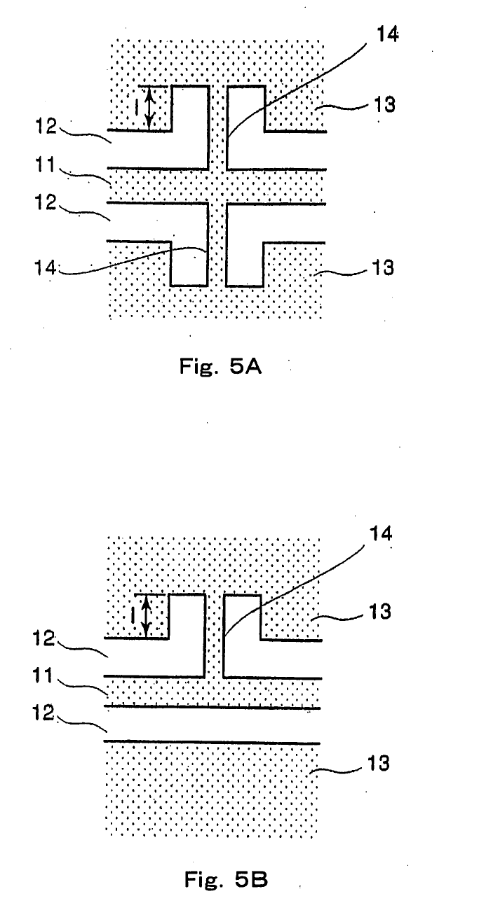

Inductance element 10 can be implemented, for example, by providing conductor piece 14 (the length of which is l), which is sufficiently short with respect to the wavelength at a desired frequency, to connect signal conductor 11 with ground conductors 13 which are formed on both sides of signal conductor 11 across gaps 12, as illustrated in FIG. 5A, when a transmission line is formed in a coplanar configuration. Alternatively, as illustrated in FIG. 5B, inductance element 10 can be implemented by providing conductor piece 14 (the length of which is l), which is sufficiently short with respect to the aforementioned wavelength, in order to connect signal conductor 11 with one ground conductor 13 of ground conductors 13 formed on both sides of signal conductor 11 across gaps 12. A coplanar type transmission line is composed of a signal conductor and ground conductors arranged to sandwich the signal conductor therebetween across predetermined gaps.

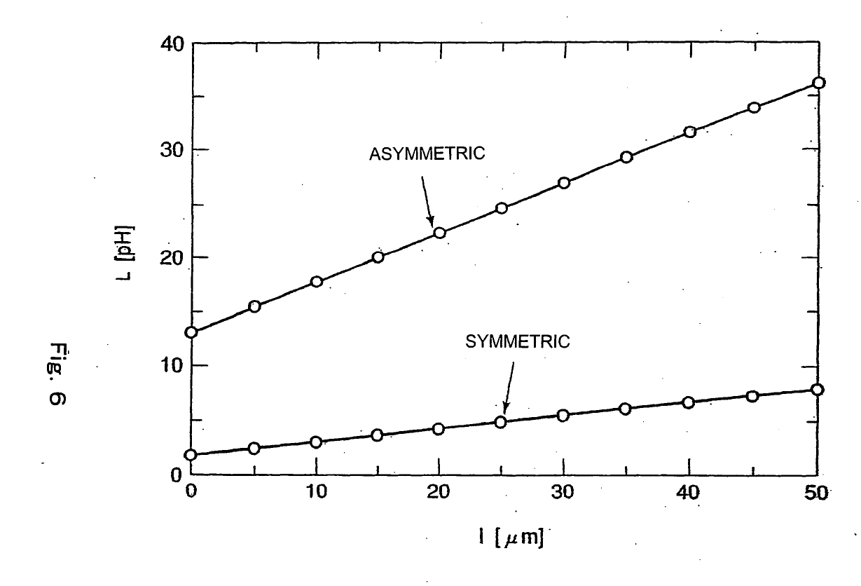

A graph shown in FIG. 6 is the result of a simulation, which represents a change in inductance L with respect to length l of conductor piece 14 when inductance element 10 is configured as illustrated in FIG. 5A (symmetric) and is configured as illustrated in FIG. 5B (asymmetric). As shown in FIG. 6, it can be seen that inductance element 10 can present a larger inductance and can be reduced in size when it is made using asymmetric conductor piece 14.

As illustrated in FIG. 4, since the negative-resistance circuit of the first embodiment is configured to provide the output terminal on the gate side of FET 1 which presents a large input impedance, the gate of FET 1 need not be substantially supplied with a current. Therefore, a distributed constant line, which has a small impedance to a direct current and an infinite impedance at a desired frequency, is not required on the output side, as is in a conventional negative-resistance circuit which supplies a predetermined bias current to a drain. Thus, the circuit configuration is simplified as compared with the conventional configuration, making it possible to reduce the size.

In such a configuration, in the negative-resistance circuit of the first embodiment, length ls1 of first distributed constant line 2a, length ld of second distributed constant line 3, and length lg of third distributed constant line 4, connected to the respective terminals of FET 1, are each adjusted, such that the negative resistance value is substantially constant in a desired frequency range. Also, the negative resistance value is adjusted by the value of inductance element 10 which is connected between the output terminal and ground potential.

Next, referring to the drawings, description will be made for the reason for which the negative-resistance value can be adjusted by the lengths of first distributed constant line 2a to third distributed constant line 4 and the value of inductance element 10 of negative-resistance circuit illustrated in FIG. 4. In the following, description will be made, by way of example, for the negative-resistance circuit illustrated in FIG. 4 in which a load of 50 Ω is connected to the output terminal thereof; capacitance element 7a has capacitance C equal to 3.0 pF; bias voltage Vd is 3.0 V; bias voltage Vg is −0.4 V; resistor 9 has resistance value R equal to 10 KΩ, and the capacitance of capacitance element 8 has a sufficiently large value required to block a direct-current component.

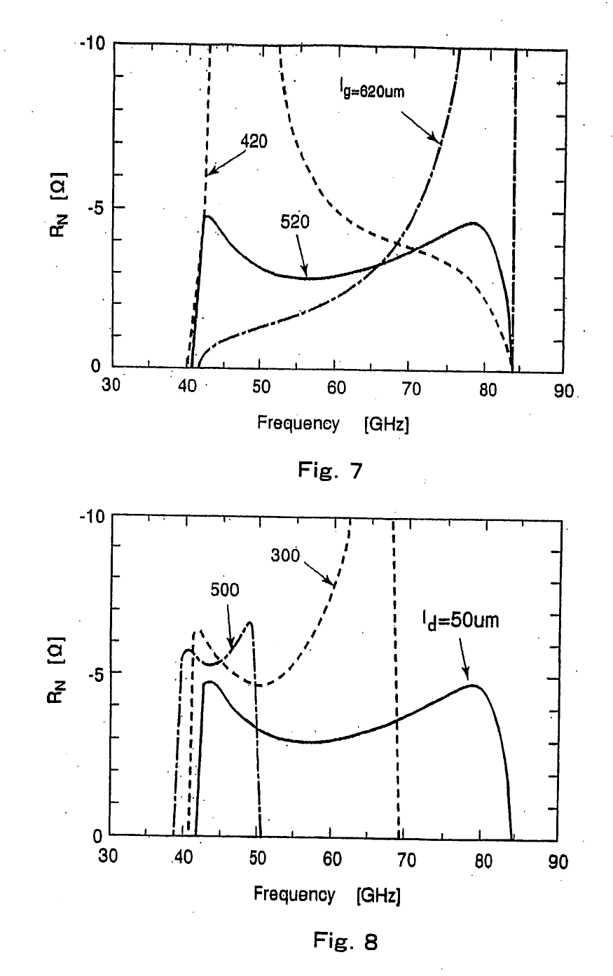

First, inductance element 10 connected to the output terminal of the negative-resistance circuit illustrated in FIG. 4 is fixed at 60 pH, and first distributed constant line 2a connected to the source of FET 1 is set to a length (ls1=700 μm) at which it is capacitive in a band (40-80 GHz) required as the negative-resistance circuit. Also, second distributed constant line 3 connected to the drain of FET 1 is set to a length (ld=50 μm) at which it is inductive in the aforementioned band. Finally, length lg of third distributed constant line 4 connected to the gate of FET 1 is adjusted such that the negative resistance value becomes substantially level within the aforementioned band. FIG. 7 shows how the frequency characteristics of the negative resistance value change depending on the length of the third distributed constant line. FIG. 7 shows the result of a simulation.

As shown in FIG. 7, the negative resistance value becomes larger at a lower frequency when length lg of third distributed constant line 4 is short (lg=420 μm), while the negative resistance value becomes larger at a higher frequency when length lg of third distributed constant line 4 is long (lg=620 μm). In the example shown in FIG. 7, it can be seen that the negative resistance value is substantially constant in a required band (40-80 GHz) when length lg of third distributed constant line 5 is 520 μm. Also, even a change in length lg of third distributed constant line 4 does not cause a change in the frequency range in which the negative resistance is achieved.

On the other hand, when length ld of second distributed constant line 3 connected to the drain of FET 1 is changed with length lg of third distributed constant line 4 fixed at 520 μm, the negative resistance characteristics are as shown in FIG. 8. FIG. 8 shows the result of a simulation.

As shown in FIG. 8, the negative resistance is achieved in a frequency range 40-80 GHz when length ld of second distributed constant line 3 is 50 μm; the negative resistance is achieved in a frequency range 40-70 GHz when ld is 300 μm; and the negative resistance is achieved in a frequency range 40-50 GHz when ld is 500 μm. In other words, it can be seen that as length ld of second distributed constant line 3 is increased, the negative resistance is achieved in a frequency range, the upper limit of which becomes lower. This is because second distributed constant line 3 is capacitive at or above the upper limit frequency at which the negative resistance is achieved.

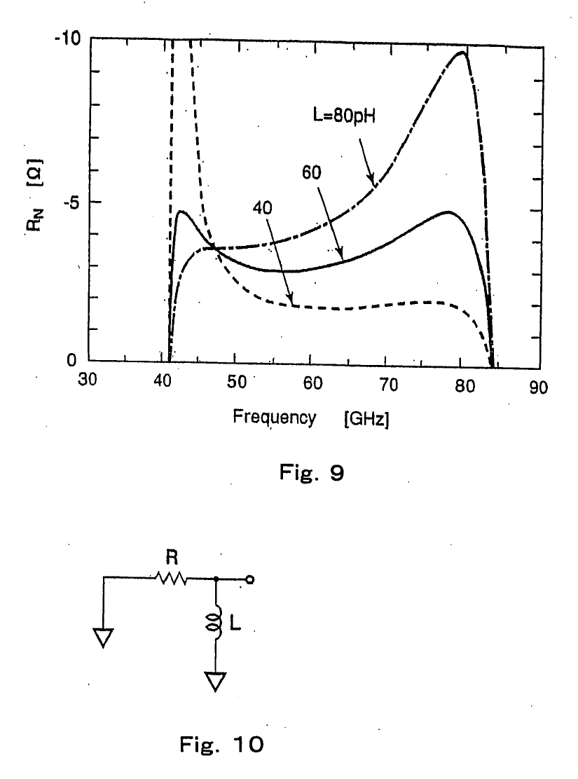

As the value of inductance element 10 alone is changed after the completion of the adjustment relying on the lengths of first distributed constant line 2a, second distributed constant line 3 and third distributed constant line 4, the negative resistance characteristics are as shown by a graph of FIG. 9. FIG. 9 shows the result of a simulation.

As shown in FIG. 9, the negative resistance value is approximately −2 Ω (value in a flat region) when value L of inductance element 10 is 40 pH; approximately −3 Ω (value in a flat region) when value L of inductance element 10 is 60 pH; and approximately −4 Ω (value in a flat region) when value L of inductance element 10 is 80 pH. In other words, the negative resistance value is proportional to the value of inductance element 10. However, in the example shown in FIG. 9, a change in the value of inductance element 10 causes a similar change in flatness of the negative resistance value.

The circuit illustrated in FIG. 4 is equivalent to a circuit shown in FIG. 10 when circuits, except for inductance element 10, are replaced by resistor R.

Therefore, impedance Z of the whole circuit illustrated in FIG. 4 can be expressed by:

$$Z = \frac{1}{\frac{1}{R} + \frac{1}{j ω L}} \\ = \frac{j ω L R}{R + j ω L} \\ = \frac{j ω L {R}^{2} + {ω}^{2} {L}^{2} R}{{R}^{2} + {ω}^{2} {L}^{2}} \qquad [ Equation 2 ]$$

where Z=0 when L=0, and Z=R when L=∞. It can be seen from this fact that the negative resistance value of the circuit illustrated in FIG. 4 can be readily adjusted by the value of inductance element 10.

### Second Embodiment

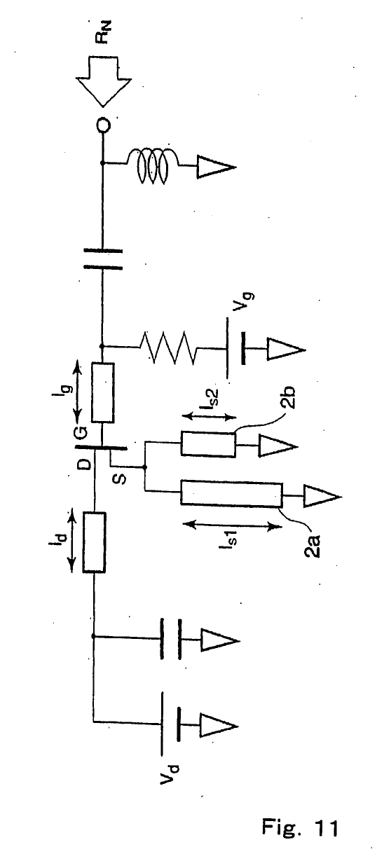

As illustrated in FIG. 11, a negative-resistance circuit according to a second embodiment comprises fourth distributed constant line 2b (the length of which is ls2) connected to source (S) of an FET in parallel with first distributed constant line 2a (the length of which is ls1) shown in FIG. 4 (where ls1>ls2). Since the remaining configuration is similar to the first embodiment, description thereon is omitted.

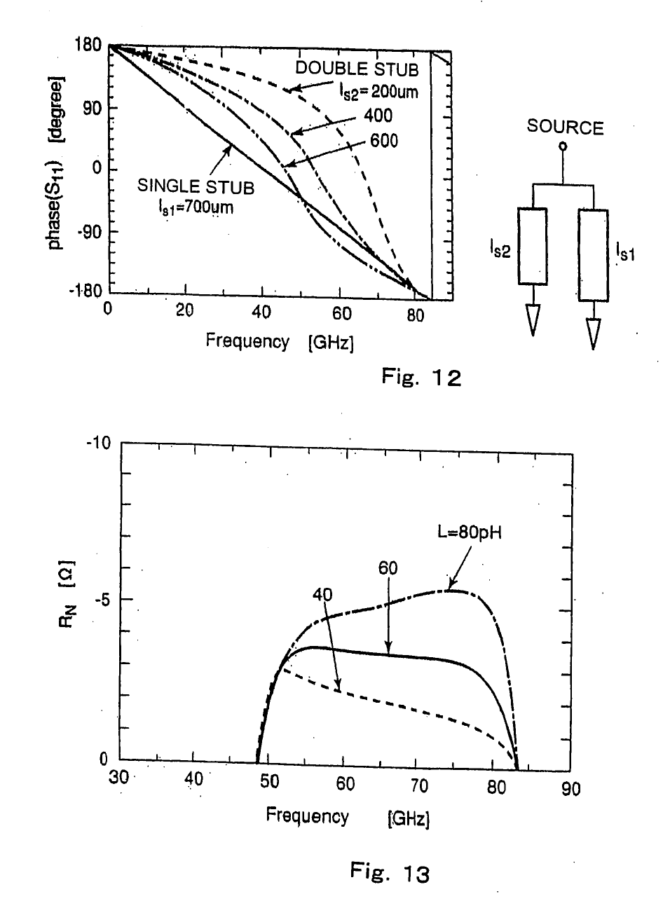

In the negative-resistance circuit of the second embodiment illustrated in FIG. 11, the phase of a reflection coefficient of first distributed constant line 2a and fourth distributed constant line 2b changes with respect to the frequency in a non-linear fashion, as viewed from the source of the FET. FIG. 12 is a graph showing this situation. FIG. 12 shows the phase characteristics with respect to a change in frequency when length ls2 of fourth distributed constant line 2b is changed under the condition of ls1>ls2, with first distributed constant line 2a having length ls1 fixed at 700 μm. A “single stub” in FIG. 12 shows the characteristic of a configuration in which first distributed constant line 2a alone is connected to the source of the FET, as in FIG. 4, while a “double stub” shows the characteristics of a configuration in which first distributed constant line 2a and fourth distributed constant line 2b are connected to the source of the FET as in FIG. 11.

As shown in FIG. 12, in the configuration in which first distributed constant line 2a alone is connected to the source of the FET, the phase linearly changes with respect to a change in frequency. On the other hand, in the configuration in which first distributed constant line 2a and fourth distributed constant line 2b are connected in parallel to the source of the FET, the phase changes non-linearly with respect to a change in frequency at or below the upper limits of the frequencies at which these distributed constant lines are capacitive, while maintaining the upper limit. It can be seen that the non-linearity can be adjusted by changing length ls2 of fourth distributed constant line 2b. However, a change in length ls2 of fourth distributed constant line 2b causes an increase in the lower limit frequency above which fourth distributed constant line 2b is capacitive.

In the negative-resistance circuit of the second embodiment, as in the first embodiment, length ls1 of the first distributed constant line, length ld of the second distributed constant line, length lg of the third distributed constant line, and fourth distributed constant line 2b, connected to the respective terminals of FET 1, are each adjusted, such that the negative resistance value is substantially constant in a desired frequency range.

In this event, in the negative-resistance circuit of the second embodiment, non-linearity can be given to a phase change with respect to a frequency change at or below the upper limit, thus making it possible to facilitate the achievement of a constant negative resistance value in a wide range as compared with the first embodiment. The negative resistance value is adjusted by the value of the inductance element connected between the output terminal and ground potential, in a manner similar to the first embodiment.

FIG. 13 is a graph showing how the frequency characteristics of the negative resistance value of the negative-resistance circuit illustrated in FIG. 11 change depending on the value of the inductance element. FIG. 13 shows the result of a simulation.

As shown in FIG. 13, the negative-resistance circuit of the second embodiment can achieve a negative resistance value which is proportional to the value of the inductance element, in a manner similar to the first embodiment. It can also be seen that the flatness of the negative resistance characteristics with respect to a change in inductance is improved as compared with the first embodiment. In the negative-resistance circuit of the second embodiment, the non-linearity of the phase exhibited by the distributed constant line connected to the source of the FET increases the frequency at which the distributed constant line converts from an inductive nature to a capacitive nature. Therefore, as shown in FIG. 13, the negative resistance is achieved at an increased lower limit frequency.

### Third Embodiment

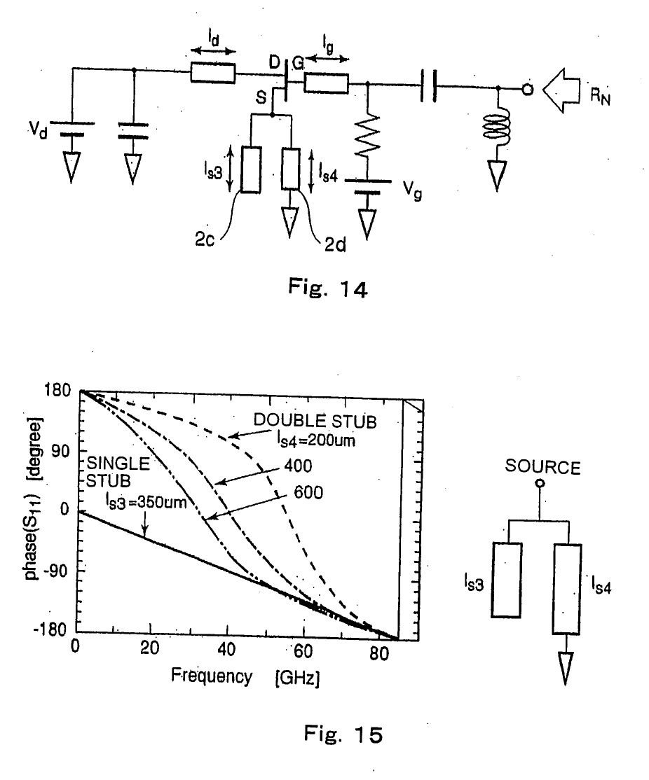

As illustrated in FIG. 14, a negative-resistance circuit according to a third embodiment comprises fifth distributed constant line 2c (the length of which is ls3) which is set to a length equal to or shorter than one-quarter wavelength at a desired frequency and has an opened leading end, and sixth distributed constant line 2d (the length of which is ls4) having a leading end connected to the ground potential, both of which are connected to the source of the FET. Since the remaining configuration is similar to the first embodiment, description thereon is omitted.

Likewise, in such a configuration, the phase of reflection coefficient of fifth distributed constant line 2c and sixth distributed constant line 2d changes non-linearly with respect to the frequency, as viewed from the source of the FET, as shown in FIG. 15. Accordingly, the negative-resistance circuit of the third embodiment can provide similar effects to those in the second embodiment.

While the second embodiment and third embodiment have shown configurations in which two distributed constant lines are connected to the source of the FET, the number of distributed constant lines connected to the source may be three or more. In this event, in the configuration in which a plurality of distributed constant lines are all short-circuited to the ground potential (see FIG. 11), any one of the distributed constant lines may be set to a length of λ/4<ls<λ/2 at which the distributed constant line is capacitive in a desired frequency range and grounds the source in a direct current manner, and the remaining distributed constant lines may be set shorter than that.

Also, in the configuration in which at least one of a plurality of distributed constant lines is opened (see FIG. 14), the distributed constant line having an opened leading end may be set to one-quarter wavelength or shorter, while the distributed constant lines having a leading end short-circuited to the ground potential may be set to one-half wavelength or shorter.

### Fourth Embodiment

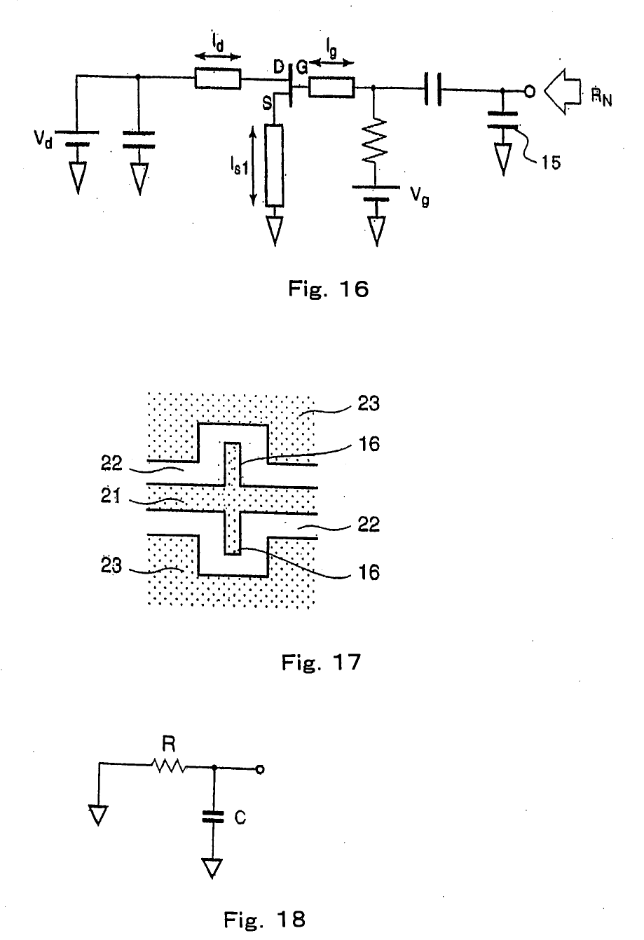

As illustrated in FIG. 16, a negative-resistance circuit according to a fourth embodiment comprises capacitance element 15 connected to the output terminal in place with the inductance element. Since the remaining configuration is similar to the first embodiment, description thereon is omitted.

Capacitance element 15 can be implemented by conductor piece 16 which is provided to branch from signal conductor 21 formed within ground conductors 23 across gaps 22, that is sufficiently short with respect to the wavelength at a desired frequency, and has opened leading ends, as illustrated in FIG. 17. By making capacitance element 5 from a conductor piece (distributed constant line), a highly accurate capacitance element can be implemented, as compared with a configuration which employs a lumped constant element.

The circuit illustrated in FIG. 16 is equivalent to a circuit illustrated in FIG. 18 when circuits, except for capacitance element 15, are replaced by resistor R.

Therefore, impedance Z of the entire circuit illustrated in FIG. 16 is calculated by:

$$Z = \frac{1}{\frac{1}{R} + j ω C} \\ = \frac{R}{1 + j ω CR} \\ = \frac{R - j ω {CR}^{2}}{1 + {ω}^{2} {C}^{2} {R}^{2}} \qquad [ Equation 3 ]$$

where Z=R when C=0, and Z=0 when C=∞. It can be seen from this fact that the negative resistance value of the circuit illustrated in FIG. 16 can be readily adjusted by the value of capacitance element 15.

### Fifth Embodiment

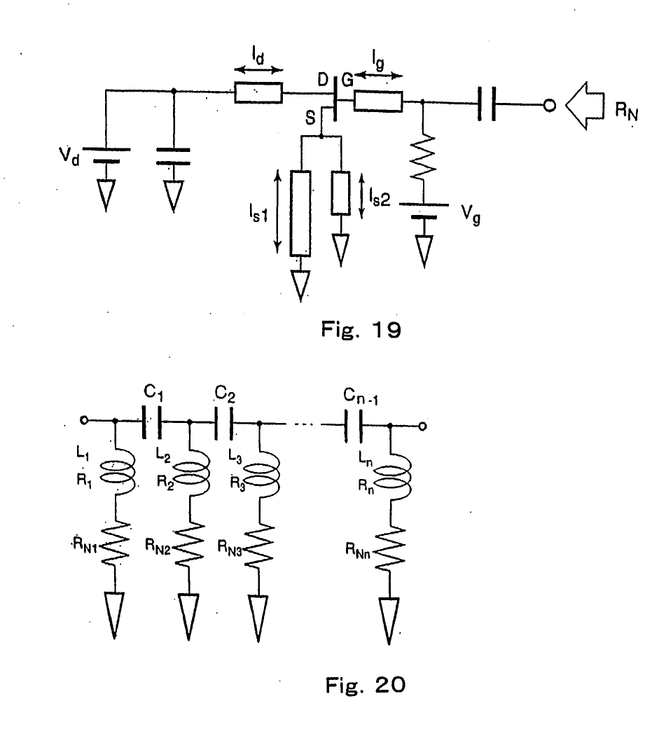

As illustrated in FIG. 19, a negative-resistance circuit according to a fifth embodiment omits the inductance element connected between the output terminal and ground potential from the configuration of the second embodiment illustrated in FIG. 11. Since the remaining configuration is similar to the second embodiment, description thereon is omitted.

As described in Background Art, the negative resistance value can also be adjusted by changing the lengths of respective distributed constant lines connected to the three terminals of an FET.

The negative-resistance circuit of this embodiment advantageously facilitates the achievement of a constant negative resistance value over a wide band because it has two distributed constant lines connected to the source of the FET in a manner similar to the negative-resistance circuit of the second embodiment. Consequently, the negative resistance value can be more readily adjusted by the lengths of the respective distributed constant lines connected to the three terminals of the FET than by the conventional negative-resistance circuit.

While the fifth embodiment has shown a configuration which omits the inductance element connected between the output terminal and ground potential from the configuration of the second embodiment illustrated in FIG. 11, similar advantages can be provided by a configuration which omits the inductance element from the configuration of the third embodiment illustrated in FIG. 14. The first embodiment to the fifth embodiment shows examples which make up the negative-resistance circuit using the field effect transistor (FET), similar characteristics and advantages can be provided by a configuration which employs a bipolar transistor instead of the FET.

Also, the negative-resistance circuit of the present invention may be a circuit configuration which changes the source for the drain of the FET shown in the first embodiment to the fifth embodiment. In this event, a plurality of distributed constant lines are connected to the drain. Though complicated in adjustments, a configuration which connects a plurality of distributed constant lines to the gate of the FET can also be allowed as an exemplary modification of the present invention.

Further, while the first embodiment to the fifth embodiment have shown examples in which the inductance element and capacitance element are implemented by providing a conductor piece on the coplanar transmission line, lumped constant elements may be used for the inductance element and capacitance element. Also, when the transmission line is a microstrip line, an inductance element may be implement by forming a substrate, on which the negative-resistance circuit is mounted, with a throughhole in communication with the ground conductor formed on the back of the substrate, and connecting the conductor piece disposed on the microstrip line to the ground conductor formed on a circuit mounting surface through the throughhole. Also, the capacitance element may be implemented by a conductor piece which is branched from the microstrip line and has an opened leading end.

### Sixth Embodiment

A sixth embodiment proposes an active filter which employs the negative-resistance circuit shown in the first embodiment to the fifth embodiment.

FIG. 20 is a circuit diagram illustrating an exemplary configuration of the active filter according to the present invention.

The active filter illustrated in FIG. 20, which is an exemplary configuration of a high pass filter, comprises a plurality of capacitance elements C₁-Cₙ₋₁ (n is a positive integer) inserted in series between an input and an output terminal; and inductance elements L₁-Lₙ and negative-resistance circuits R_{N1}-R_{Nn} each connected in series between a connection node which is between respective capacitance elements C₁-Cₙ₋₁ and the ground potential. Any of the circuits shown in the first embodiment to the fifth embodiment is used for negative-resistance circuits R_{N1}-R_{Nn}.

Since a main cause for a loss of a high pass filter in such a configuration is a loss due to the inductance elements, the high pass filter illustrated in FIG. 20 can be regarded as lossless when resistive components of respective inductance element L₁-Lₙ are equal to resistance values R_{N1}-R_{Nn} of the negative-resistance circuits.

Inductance elements L₁-Lₙ can be each implemented by a distributed constant line (with characteristic impedance Z0, attenuation constant α, propagation coefficient β, and length lₙ) which is sufficiently shorter than one-quarter wavelength (λ/4) at a desired frequency, in which case the inductance can be approximated by Equation (5). Also, a required negative resistance value can be expressed by Equation (6):

$$\begin{matrix}[ Equation 4 ] & \\ {L}_{n} = \frac{{Z}_{0} β {l}_{n}}{ω} & ( 5 ) \\ {R}_{Nn} = \frac{- Z ( {ⅇ}^{2 {l}_{n} α} - 1 )}{{ⅇ}^{2 {l}_{n} α} + 1} & ( 6 )\end{matrix}$$

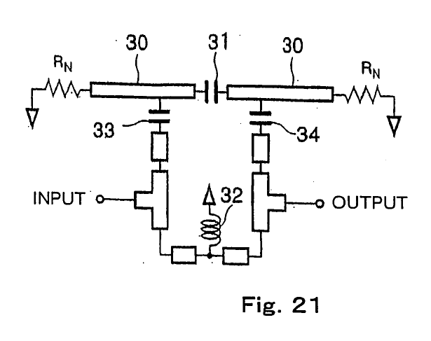

The negative-resistance circuits shown in the first embodiment to the fifth embodiment cannot implement a low pass filter because they are one-terminal-pair circuits, but a bandpass filter can be implemented when configuring, for example, a parallel connection type filter illustrated in FIG. 21.

The bandpass filter illustrated in FIG. 21 comprises a plurality (two in FIG. 21) of negative-resistance circuits R_{N} and resonators 30; first capacitance element 31 for coupling between resonators 30; inductance element 32 connected to the ground potential and a connection node of an input terminal with an output terminal; second capacitance element 33 for coupling between one resonator 30 and the input terminal; and third capacitance element 34 for coupling between the other resonator 30 and the output terminal. Any of the circuits shown in the first embodiment to the fifth embodiment is used for negative-resistance circuit R_{N}, while resonator 30 is made, for example, using a distributed constant line which has a length equal to one-quarter wavelength at a desired frequency.

Inductance element 32 in turn can be formed of the distributed constant line illustrated in FIG. 5A or 5B, while first capacitance element 31, second capacitance element 33, and third capacitance element 34 can be each formed of two transmission lines arranged with a predetermined gap defined therebetween.

While the bandpass filter illustrated in FIG. 21 has shown a configuration which employs two negative-resistance circuits R_{N} and resonators, a bandpass filter can be made up of any number of negative-resistance circuits R_{N} and resonators. The configuration of such a bandpass filter is described, for example, in Uwe Rosenberg et al., “Novel Coupling Schemes for Microwave Resonator Filters,” IEEE IMS2002 Digest, pp. 1605-1608.

Since the active filter of the present invention is configured using the negative-resistance circuit which has a constant negative resistance value over a wide band, shown in the first embodiment to the fifth embodiment, it is possible to provide a filter circuit which operates stably without oscillating.

1-24. (canceled)

25. A negative-resistance circuit having a transistor and distributed constant lines respectively connected to three terminals thereof, said negative-resistance circuit characterized by comprising:
an inductance element connected between an output terminal of said negative-resistance circuit and a ground potential for adjusting a negative resistance value; and
a plurality of distributed constant lines connected in parallel to at least one of the three terminals of said transistor.

26. The negative-resistance circuit according to claim 25, wherein:
said inductance element comprises a distributed constant line shorter than one-quarter wavelength at a desired frequency for connecting between a signal conductor and the ground potential.

27. The negative-resistance circuit according to claim 25, wherein:
said distributed constant line is a coplanar type one composed of a signal conductor and ground conductors disposed to sandwich said signal conductor with predetermined gaps therebetween, and
said inductance element comprises a conductor piece which traverses only one of said gaps to connect said signal conductor with said ground conductor.

28. A negative-resistance circuit having a transistor and distributed constant lines respectively connected to three terminals thereof, said negative-resistance circuit characterized by comprising:
a capacitance element connected between an output terminal of said negative-resistance circuit and a ground potential for adjusting a negative resistance value,
a plurality of distributed constant lines connected in parallel to at least one of the three terminals of said transistor.

29. The negative-resistance circuit according to claim 28, wherein:
said capacitance element comprises a distributed constant line which is branched from a signal conductor, has an opened leading end, and is shorter than one-quarter wavelength at a desired frequency.

30. The negative-resistance circuit according to claim 28, wherein:
said distributed constant line is a coplanar type one composed of a signal conductor and ground conductors disposed to sandwich said signal conductor with predetermined gaps therebetween, and
said capacitance element comprises a conductor piece which is branched from said signal conductor and has an opened leading end.

31. A negative-resistance circuit having a transistor and distributed constant lines respectively connected to three terminals thereof, said negative-resistance circuit characterized in that:
a plurality of distributed constant lines are connected in parallel to at least one of the three terminals of said transistor.

32. The negative-resistance circuit according to claim 25, wherein:
one of said plurality of distributed constant lines connected in parallel is a distributed constant line which is longer than one-quarter wavelength and shorter than one-half wavelength at a desired frequency, and has a leading end connected to a ground potential.

33. The negative-resistance circuit according to claim 25, wherein:
one of said plurality of distributed constant lines connected in parallel is a distributed constant line which is shorter than one-quarter wavelength at a desired frequency, and has an opened leading end, and
the remaining distributed constant lines are distributed constant lines each having a leading end short-circuited to a ground potential.

34. The negative-resistance circuit according to claim 28, wherein:
one of said plurality of distributed constant lines connected in parallel is a distributed constant line which is longer than one-quarter wavelength and shorter than one-half wavelength at a desired frequency, and has a leading end connected to a ground potential.

35. The negative-resistance circuit according to claim 28, wherein:
one of said plurality of distributed constant lines connected in parallel is a distributed constant line which is shorter than one-quarter wavelength at a desired frequency, and has an opened leading end, and
the remaining distributed constant lines are distributed constant lines each having a leading end short-circuited to a ground potential.

36. The negative-resistance circuit according to claim 31, wherein:
one of said plurality of distributed constant lines connected in parallel is a distributed constant line which is longer than one-quarter wavelength and shorter than one-half wavelength at a desired frequency, and has a leading end connected to a ground potential.

37. The negative-resistance circuit according to claim 31, wherein:
one of said plurality of distributed constant lines connected in parallel is a distributed constant line which is shorter than one-quarter wavelength at a desired frequency, and has an opened leading end, and
the remaining distributed constant lines are distributed constant lines each having a leading end short-circuited to a ground potential.

38. The negative-resistance circuit according to claim 25, wherein:
said transistor is a field effect transistor, and
said terminal to which said plurality of distributed constant lines are connected in parallel is a source of said field effect transistor.

39. The negative-resistance circuit according to claim 28, wherein:
said transistor is a field effect transistor, and
said terminal to which said plurality of distributed constant lines are connected in parallel is a source of said field effect transistor.

40. The negative-resistance circuit according to claim 31, wherein:
said transistor is a field effect transistor, and
said terminal to which said plurality of distributed constant lines are connected in parallel is a source of said field effect transistor.

41. The negative-resistance circuit according to claim 38, wherein:
an output terminal of said negative-resistance circuit is disposed through a distributed constant line connected to a gate of said field effect transistor, wherein:
said negative-resistance circuit comprises:
a bias power source for supplying said gate with a predetermined DC voltage; and
a resistor connected between said bias power source and said distributed constant line connected to said gate.

42. The negative-resistance circuit according to claim 39, wherein:
an output terminal of said negative-resistance circuit is disposed through a distributed constant line connected to a gate of said field effect transistor, wherein:
said negative-resistance circuit comprises:
a bias power source for supplying said gate with a predetermined DC voltage; and
a resistor connected between said bias power source and said distributed constant line connected to said gate.

43. The negative-resistance circuit according to claim 40, wherein:
an output terminal of said negative-resistance circuit is disposed through a distributed constant line connected to a gate of said field effect transistor, wherein:
said negative-resistance circuit comprises:
a bias power source for supplying said gate with a predetermined DC voltage; and
a resistor connected between said bias power source and said distributed constant line connected to said gate.

44. An active filter comprising:
the negative-resistance circuit according to claim 25; and
a resonator connected in series with said negative-resistance circuit.

45. An active filter comprising:
the negative-resistance circuit according to claim 28; and
a resonator connected in series with said negative-resistance circuit.

46. An active filter comprising:
the negative-resistance circuit according to claim 31; and
a resonator connected in series with said negative-resistance circuit.
